(19) United States
(12) Patent Application Publication
(10) Pub. No.: US 2014/0144686 A1
(43) Pub. Date: May 29, 2014

(54) WIRING BOARD WITH BUILT-IN ELECTRONIC COMPONENT AND METHOD FOR MANUFACTURING WIRING BOARD WITH BUILT-IN ELECTRONIC COMPONENT

(71) Applicant: IBIDEN CO., LTD., Ogaki-shi (JP)

(72) Inventor: Keisuke SHIMIZU, Ogaki-shi (JP)

(73) Assignee: IBIDEN CO., LTD., Ogaki-shi (JP)

(21) Appl. No.: 14/093,099

(22) Filed: Nov. 29, 2013

(30) Foreign Application Priority Data
Nov. 28, 2012 (JP) 2012-259776

(51) Int. Cl. H05K 1/18; H05K 1/02; H05K 3/30

(52) U.S. Cl. CPC H05K 1/185; H05K 3/306; H05K 1/0271
USPC 174/258; 29/837

(57) ABSTRACT

A wiring board for a built-in electronic component includes a substrate having a cavity portion, an electronic component accommodated in the cavity portion of the substrate, a filling resin material filling a space formed between the electronic component and an inner wall of the substrate forming the cavity portion, an insulation layer formed on the substrate and the electronic component accommodated in the cavity portion of the substrate, and a via conductor formed in the insulation layer such that the via conductor is connected to a connection terminal of the electronic component. The substrate has projection portions formed on the inner wall of the substrate such that the projection portions project toward the electronic component accommodated in the cavity portion of the substrate.

### CROSS-REFERENCE TO RELATED APPLICATIONS

The present application is based upon and claims the benefit of priority to Japanese Patent Application No. 2012-259776, filed Nov. 28, 2012, the entire contents of which are incorporated herein by reference.

### BACKGROUND OF THE INVENTION

1. Field of the Invention

The present invention relates to a wiring board with a built-in electronic component, the wiring board having an active electronic component such as a semiconductor element or the like or a passive electronic component such as a chip condenser or the like, and a method for manufacturing the wiring board with a built-in electronic component.

2. Description of Background Art

An IC chip may be mounted on a package substrate or may be built into a printed wiring board. JP 2006-19441 A describes a wiring board with a built-in semiconductor element in which a cavity is provided in a resin substrate or a resin layer and the semiconductor element is built into the cavity. The entire contents of this publication are incorporated herein by reference.

### SUMMARY OF THE INVENTION

According to one aspect of the present invention, a wiring board for a built-in electronic component includes a substrate having a cavity portion, an electronic component accommodated in the cavity portion of the substrate, a filling resin material filling a space formed between the electronic component and an inner wall of the substrate forming the cavity portion, an insulation layer formed on the substrate and the electronic component accommodated in the cavity portion of the substrate, and a via conductor formed in the insulation layer such that the via conductor is connected to a connection terminal of the electronic component. The substrate has projection portions formed on the inner wall of the substrate such that the projection portions project toward the electronic component accommodated in the cavity portion of the substrate.

According to another aspect of the present invention, a method for manufacturing a wiring board having a built-in electronic component includes preparing a substrate having a cavity portion and projection portions on an inner wall of the substrate forming the cavity portion, placing an electronic component in the cavity portion of the substrate such that the electronic component is accommodated in the cavity portion of the substrate, filling a filling resin material into a space formed between the electronic component and the inner wall of the substrate forming the cavity portion, forming an insulation layer on the substrate and the electronic component accommodated in the cavity portion of the substrate, and forming a via conductor in the insulation layer such that the via conductor is connected to a connection terminal of the electronic component. The projection portions are formed on the inner wall of the substrate such that the projection portions project toward the electronic component accommodated in the cavity portion of the substrate.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a wiring board with a built-in electronic component according to a first embodiment of the present invention;

FIGS. 2A, 2B, 2C are each a cross-sectional view of an insulative base material according to the first embodiment;

FIGS. 3A to 3F are process drawings illustrating a method for manufacturing the wiring board with a built-in electronic component according to the first embodiment;

FIGS. 4A to 4E are process drawings illustrating the method for manufacturing the wiring board with a built-in electronic component according to the first embodiment;

FIGS. 5A to 5D are process drawings illustrating the method for manufacturing the wiring board with a built-in electronic component according to the first embodiment;

FIG. 6A is a process drawing illustrating the method for manufacturing the wiring board with a built-in electronic component according to the first embodiment;

FIGS. 7A, 7B are process drawings illustrating the method for manufacturing the wiring board with a built-in electronic component according to the first embodiment;

FIG. 8 is a plan view illustrating a magnified through hole;

FIGS. 9A to 9D are process drawings illustrating a method for manufacturing the wiring board with a built-in electronic component according to a first modified example of the first embodiment;

FIG. 10 is a cross-sectional view of a wiring board with a built-in electronic component according to a second modified example of the first embodiment;

FIGS. 11A, 11B are plan views each illustrating projections provided in the through hole;

FIGS. 12A to 12D are plan views each illustrating projections provided in the through hole;

FIG. 13 is a plan view illustrating projections provided in the through hole; and

FIG. 14 is a graph illustrating a relationship between the height of projections and the amount of warping of the wiring board with a built-in electronic component.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

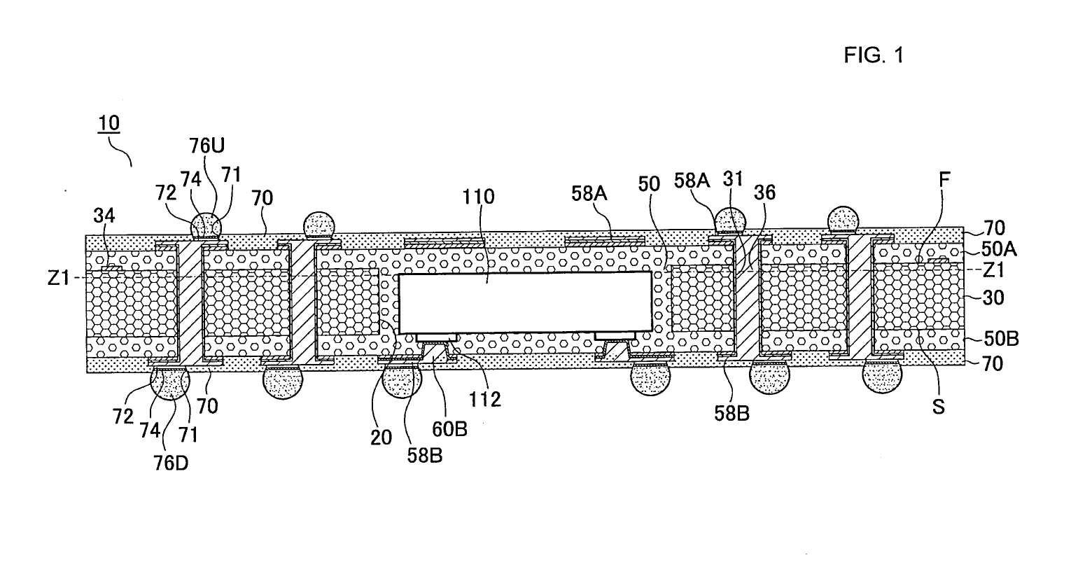

A cross-sectional view of a wiring board 10 with a built-in electronic component according to a first embodiment of the present invention is illustrated in FIG. 1. The wiring board 10 with a built-in electronic component is provided with an insulative base material 30 having a first surface (F) and second surface (S) on its opposite side, and an alignment mark 34 is formed on the first surface (F) of the insulative base material 30. In the insulative base material 30, there is provided a through hole 20, and a semiconductor element 110 is accommodated in through hole 20.

A first buildup layer is formed on both the semiconductor element 110 and the first surface (F) of the insulative base material 30. The first buildup layer is provided with an insulation layer (50A) formed so as to cover the semiconductor element 110 and the first surface (F) of the insulative base material 30, and a conductive layer (58A) on the insulation layer (50A). A second buildup layer is formed on the semiconductor element 110 and the second surface (S) of the insulative base material 30. The second buildup layer is provided with an insulation layer (50B) formed on the semiconductor element 110 and the second surface (S) of the insulative base material 30, and a conductive layer (58B) on the insulation layer (50B). There is formed a through hole 31 that penetrates through the insulative base material 30, insulation layer (50A) and insulation layer (50B); in the through hole 31, a through-hole conductor 36 is formed by filling a plating film. The end portion of the through-hole conductor 36 on its first-surface side is connected to the conductive layer (58A) on the insulation layer (50A), and the end portion of the through-hole conductor 36 on its second-surface side is connected to the conductive layer (58B) on the insulation layer (50B). In the insulation layer (50B), there is formed a via conductor (60B) for connection to a connection terminal 112 of the semiconductor element 110, and the end portion of the via conductor (60B) on its second-surface side is connected to the conductive layer (58B) on the insulation layer (50B).

A solder resist layer 70 having an opening 71 is formed on each of the first buildup layer and the second buildup layer. Each of the conductive layers (58A, 58B) exposed due to the opening 71 functions as a pad. Metal films (71, 74) composed of Ni/Au, Ni/Pd/Au or the like are formed on the pad, and solder bumps (76U, 76D) are formed on the metal films (71, 74), respectively. An IC chip is mounted on the wiring board 10 with a built-in electronic component through the solder bump (76U). Then, the wiring board 10 with a built-in electronic component is mounted on a motherboard through the solder bump (76D).

In the wiring board 10 with a built-in electronic component of the first embodiment, the semiconductor element 110 is accommodated inside the through hole 20 of the insulative base material 30. The through hole 20 is filled with a filling resin 50, and the gap between the semiconductor element 110 and the side wall of the through hole 20 (the side wall of the insulative base material 30 exposed by the through hole 20) is also filled with the filling resin 50. The semiconductor element 110 is thereby secured in the through hole 20.

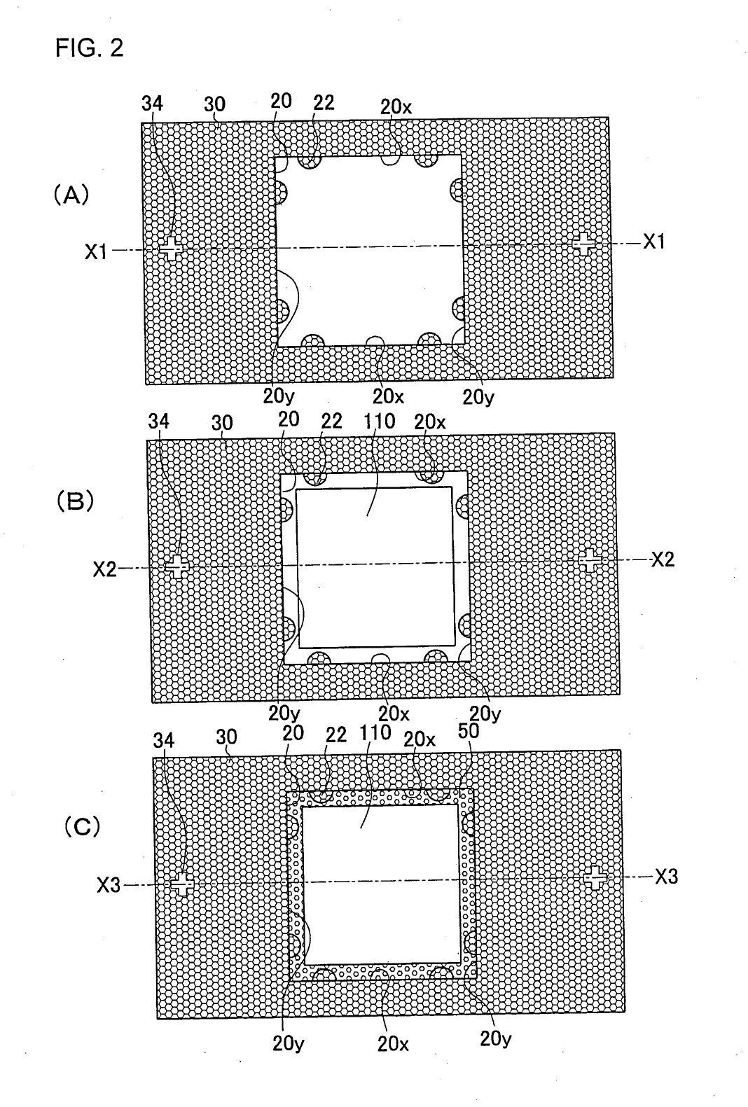

FIG. 2C is a plan view of the insulative base material 30 before the through-hole conductor is formed, corresponding to the cross section along line (Z1-Z1) in FIG. 1. The cross section along line (X3-X3) in FIG. 2C corresponds to FIG. 1. The through-hole (cavity) 20 is formed in a rectangular shape, and has side walls (20x, 20x) facing each other across the line (X3-X3) in the drawing and side walls (20y, 20y) facing each other along line (X3-X3). On each of the side walls, two projections 22 are formed so as to protrude toward the semiconductor element 110. The projections 22 are disposed in symmetrical positions by interposing the semiconductor element 110.

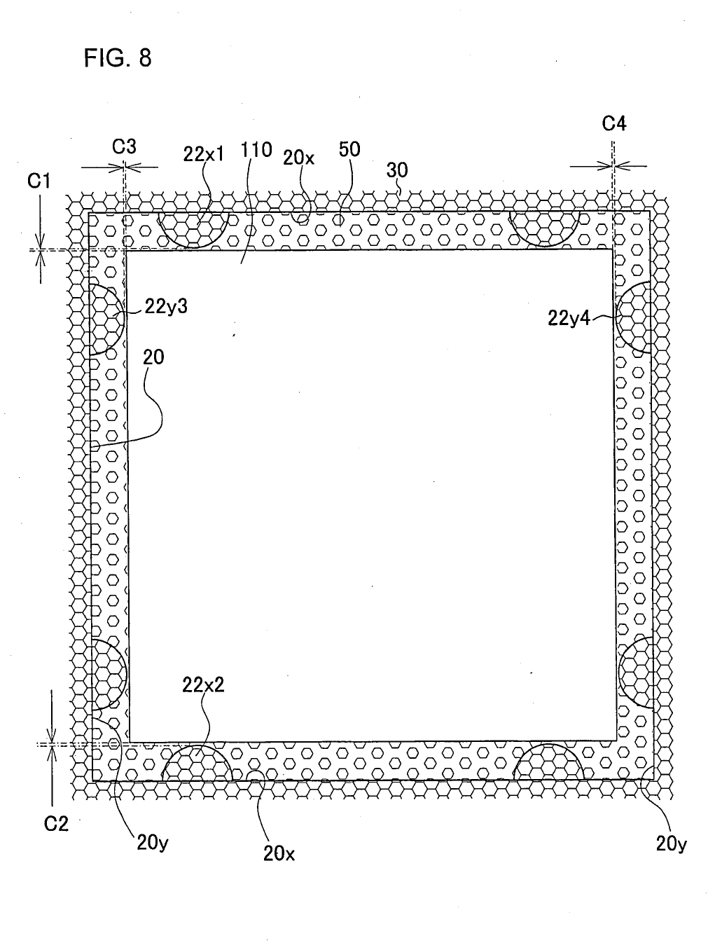

FIG. 8 is a plan view illustrating the cavity 20 on a magnified scale.

A clearance (C1) of 2 μm is provided between the semiconductor element 110 and the projection (22x1) formed on the inner wall (20x) on the upper side in the drawing. There is also provided a clearance (C2) of 2 μm between the semiconductor element 110 and the projection (22x2) facing the projection (22x1). Likewise, a clearance (C3) of 1 μm is provided between the semiconductor element 110 and the projection (22y3) formed on the inner wall (20y) on the left side in the drawing, and a clearance (C4) of 2 μm is provided between the semiconductor element 110 and the projection (22y4) facing the projection (22y3). Here, since there is a minute clearance between the semiconductor element 110 and the tip end of each of the projections 22, it is preferred that the clearances between the semiconductor element 110 and the tip ends of the projections 22 are filled with the filling resin to lessen the stress applied to the semiconductor element 110.

In the wiring board 10 with a built-in electronic component of the first embodiment, since there are provided the projections 22, which protrude toward the semiconductor element 110 and control the positional shift thereof, on the inner walls (20x, 20y) of the cavity 20 for accommodating the semiconductor element 110, the accuracy of positioning the semiconductor element 110 with respect to the cavity 20 is enhanced and the amount of positional shift of the semiconductor element 110 in the cavity 20 decreases. In addition, since the projections 22 are provided for positioning and the size of the cavity 20 may not be reduced in response to the size of the semiconductor element 110, the cavity 20 can be filled with the filling resin 50 in an amount sufficient to relieve stress caused by the difference in thermal expansion coefficients of the semiconductor element 110 and the insulative base material 30, and there is hardly any occurrence of warping of the wiring board 10 with a built-in electronic component due to the stress caused by the difference in thermal expansion coefficients. Here, the elastic modulus of the filling resin 50 is 20 GPa, the elastic modulus of the insulative base material 30 is 30 GPa, and the elastic modulus of the semiconductor element 110 is 100 GPa. By rendering the elastic modulus of the filling resin 50 to be lower than the elastic modulus of each of the insulative base material 30 and the semiconductor element 110, stress caused by the difference in thermal expansion coefficients is mitigated.

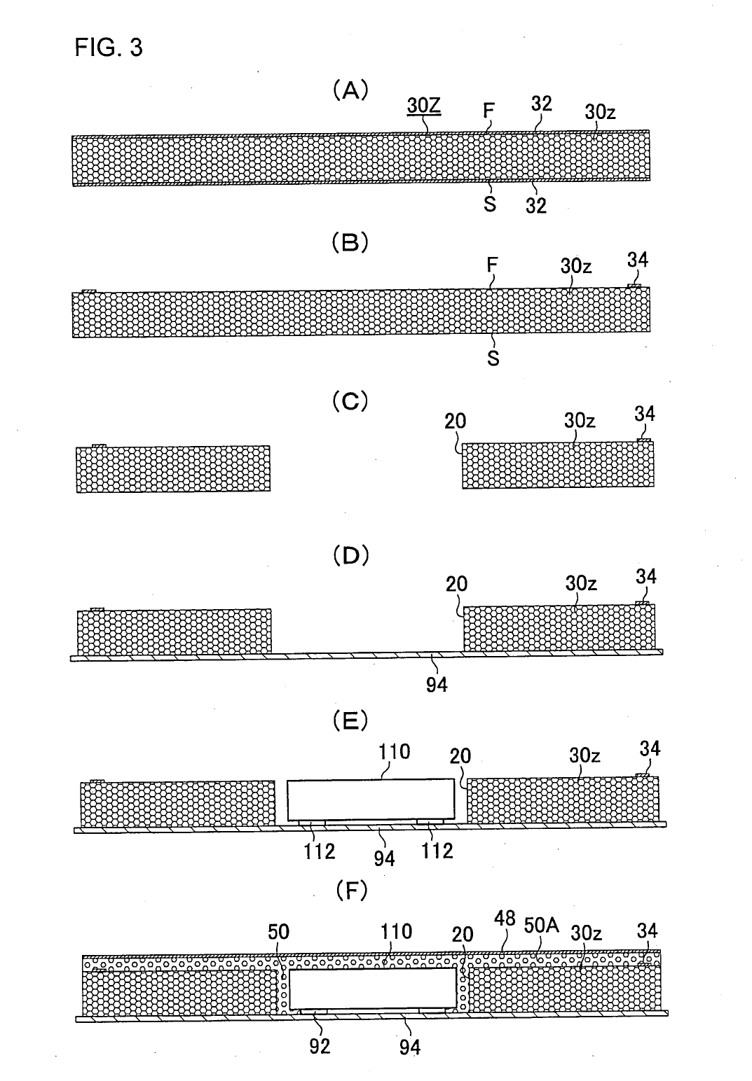

A method for manufacturing the wiring board 10 with a built-in electronic component of the first embodiment is illustrated in FIGS. 3A, 3B, 3C, 3D, 3E, 3F to FIG. 6A.

(1) A double-sided copper-cladded laminated board (30Z) composed of the insulative base material (30z) and copper foils 32 laminated on both of its sides is a starting material. The insulative base material (30z) has the first surface (F) and second surface (S) on the opposite side. Black-oxide treatment (not illustrated) is performed on the surface of the copper foil 32 (refer to FIG. 3A).

(2) The copper foil 32 is patterned, and an alignment mark 34 is formed on the first surface (F) of the insulative base material (30z).

(3) Positioning is conducted with reference to the alignment mark 34, and laser is applied to the insulative base material (30z) to form a through hole 20 therein (refer to FIG. 3C). The cross section along line (X1-X1) in the plan view of FIG. 2A corresponds to FIG. 3C. As described above with reference to FIG. 2C, the through-hole (cavity) 20 is formed in a rectangular shape, and has side walls (20x, 20x) facing each other across the line (X1-X1) in the drawing and side walls (20y, 20y) facing each other along line (X1-X1). On each of the side walls, two projections 22 having an arc-shaped cross-section are formed. The projections 22 are disposed so as to face the projections 22 on the opposite side wall.

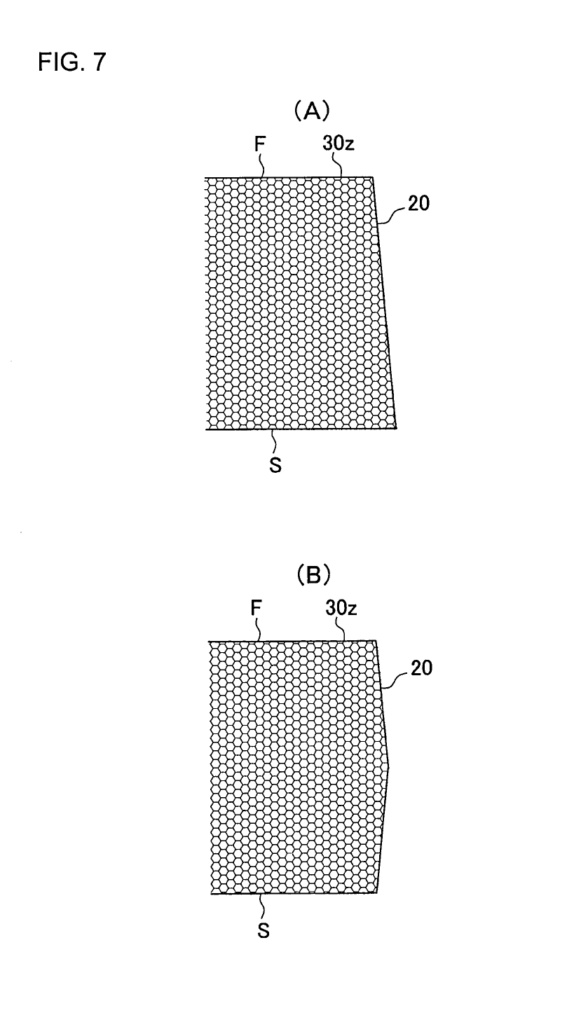

FIG. 7A is a cross-sectional view illustrating the through hole 20 on a magnified scale. In the first embodiment, by applying laser slightly inclined from the vertical, the side wall is slightly inclined so that the opening area is reduced from the first surface (F) toward the second surface (S). It is thereby facilitated to accommodate an electronic component in the through hole 20.

(4) On the second surface (S) of the insulative base material (30z), a tape 94 is stuck, and the through hole 20 is blocked with the tape 94 (refer to FIG. 3D). As an example of the tape 94, a PET film is listed.

(5) On the tape 94 exposed due to the through hole 20, the semiconductor element 110 is placed by being positioned through the alignment mark 34 (refer to FIG. 3E). The cross section along line (X2-X2) in the plan view of FIG. 2B corresponds to FIG. 3E. In the first embodiment, there are provided the projections 22, which protrude toward the semiconductor element 110 and restrain its position, on the inner walls (20x, 20y) of the cavity 20 for accommodating the semiconductor element 110. The tip ends of the projections 22 settle the position of the semiconductor element 110 by being in contact therewith or through a slight clearance on the order of several tens of μm. The accuracy of positioning the semiconductor element 110 with respect to the through hole 20 is enhanced and the amount of positional shift of the semiconductor element 110 in the through hole 20 decreases.

(6) On the first surface (F) of the insulative base material (30z), a B-stage prepreg and a copper foil 48 are laminated. Resin oozes from the prepreg by means of thermo-pressing and enters the through hole 20. The through hole 20 is thereby filled with the filling resin (resin filler) 50 and, at the same time, an insulation layer (50A) is formed (refer to FIG. 3F). The gap between the semiconductor element 110 and the inner wall of the through hole 20 is filled with the filling resin 50, and the semiconductor element 110 is secured to the insulative base material (30z). An interlayer insulation-layer resin film may be laminated instead of the prepreg. The prepreg has a reinforcing material such as a glass fiber cloth or the like, while the interlayer insulation-layer resin film does not have any reinforcing material. Both are preferred to contain inorganic particles such as glass particles or the like. The filling resin 50 contains inorganic particles such as silica particles or the like.

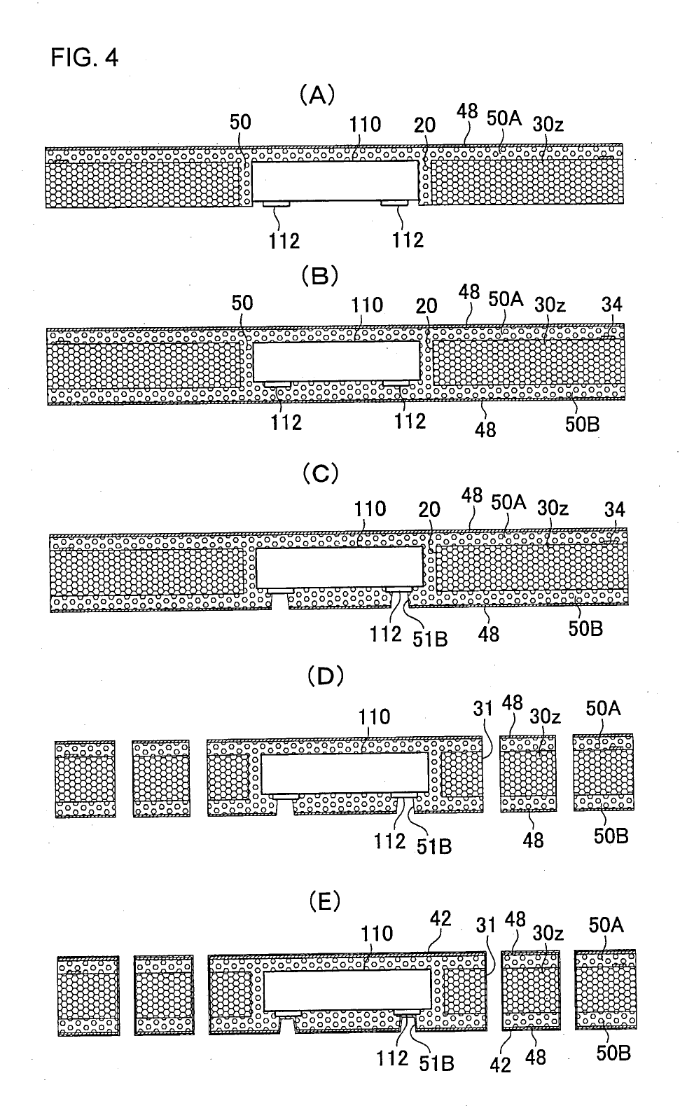

(7) After the tape 94 has been peeled off, residues on electrodes 112 of the semiconductor element 110 are removed through plasma processing (refer to FIG. 4A).

(8) On the second surface (S) of the insulative base material (30z), the B-stage prepreg and the copper foil 48 are laminated. The prepreg on the first and second surfaces of the insulative base material (30z) is cured, and the insulation layers (interlayer resin insulation layer) (50A, 50B) are thereby formed on the first and second surfaces of the insulative base material (30z) (refer to FIG. 4B).

(9) In the insulation layer (50B), openings (51B) are formed, which cause via conductors to access the electrodes 112 of the semiconductor element 110 by applying CO2 laser onto the second surface (S) (refer to FIG. 4C).

(10) Through holes 31 are formed, which pierce the insulation layer (50A), insulative base material (30z) and insulation layer (50B), by means of CO2 laser or drilling (refer to FIG. 4D).

(11) On the copper foils 48 and the inner wall of the openings (51B), electroless-plated films 42 are formed using an electroless plating process (refer to FIG. 4E).

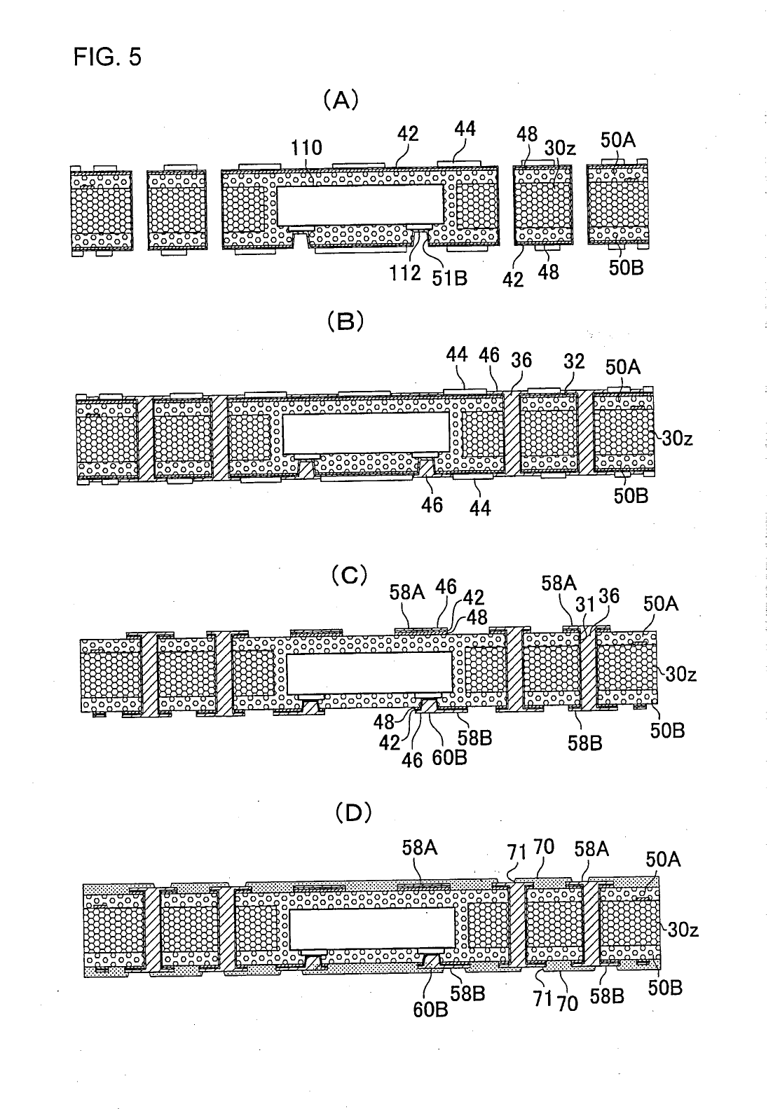

(12) Plating resists are formed on the electroless-plated films 42 (refer to FIG. 5A).

(13) An electrolytic-plated film 46 is formed on the electroless-plated film 42 exposed from the plating resists 44, and the through hole 31 is also filled with the electrolytic-plated film 46 using an electrolytic plating process (refer to FIG. 5B).

The plating resist 44 is removed by use of 5% NaOH. Then, the electroless-plated film 42 exposed from the electrolytic-plated film 46 is removed by means of etching, and the conductive layers (58A, 58B), via conductors (60B) and through-hole conductors 36 are formed, each composed of the electroless-plated film 42 and electrolytic-plated film 46 (refer to FIG. 5C).

(15) A solder resist layer 70 having openings 71 is formed on each of the insulation layers (50A, 50B)(refer to FIG. 5D). The openings 71 cause the conductive layers (58A, 58B) to be exposed, and the exposed portions each function as a pad.

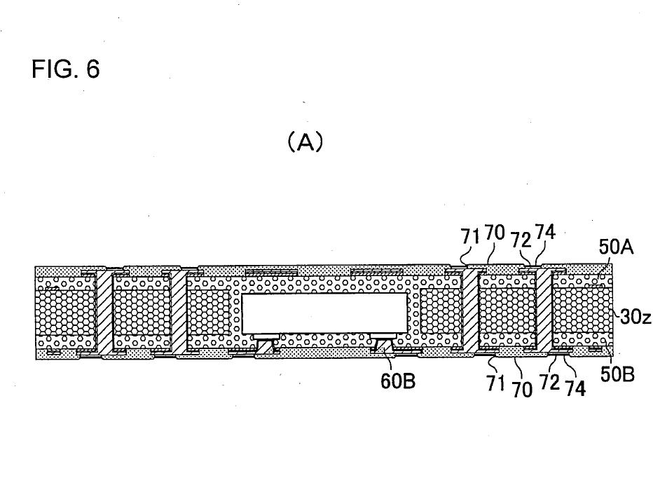

(16) On the pad in the opening 71, there is formed a metal film composed of a nickel layer 72 and gold layer laminated thereon (refer to FIG. 6A). Besides the nickel/gold layer, another metal layer composed of nickel, palladium and gold layers may be used. In the wiring board 10 with a built-in electronic component illustrated in FIG. 1, the via conductors (60B) are provided only in the second buildup layer.

(17) After that, the solder bump (76U) is formed on the pad of the first buildup layer, and the solder bump (76D) is formed on the pad of the second buildup layer. The wiring board 10 with a built-in electronic component having the solder bumps is thus completed (refer to FIG. 1).

The IC chip is mounted on the wiring board 10 with a built-in electronic component through the solder bump (76U). After that, the wiring board 10 with a built-in electronic component is mounted on the motherboard through the solder bump (76D) (not illustrated).

### First Modified Example of First Embodiment

FIG. 7B illustrates a through hole 20 formed in the insulative base material (30z) of the wiring board 10 with a built-in electronic component according to a first modified example of the first embodiment. The side wall is slightly inclined so that the opening area is reduced from the first surface (F) toward the middle, and is also slightly inclined so that the opening area is reduced from the second surface (S) toward the middle. Since the shape of the modified example of the first embodiment can be formed by irradiating laser from both the first and second surfaces, there is such an advantage that it is easy to form the through hole 20 when the insulative base material (30z) is thick.

### Second Modified Example of First Embodiment

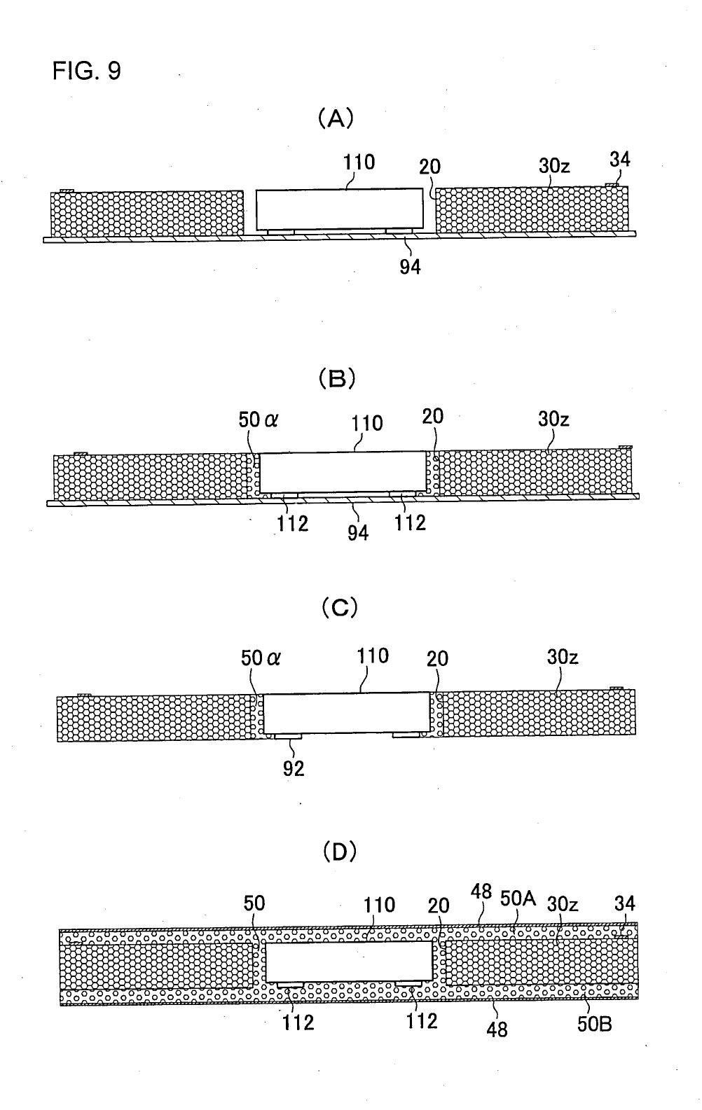

FIGS. 9A to 9D illustrate a method for manufacturing the wiring board 10 with a built-in electronic component according to a second modified example of the first embodiment. As with the case of the first embodiment described above with reference to FIGS. 3A to 3D, the semiconductor element 110 is placed on the tape 94 exposed by the through hole 20 (refer to FIG. 9A), and a filling resin (50α) is filled between the through hole 20 and the semiconductor element 110. Here, a resin similar to the resin composing the insulation layers (50A, 50B) is used as the filling resin (50α), and the thermal expansion coefficient of the filling resin (50α) is prepared to have an intermediate value between the thermal expansion coefficients of the semiconductor element 110 and the insulative base material (30z). After the filling resin (50α) has been semi-cured, the tape 94 is peeled off (refer to FIG. 9C). After that, the prepreg and the copper foil 48 are laminated, and the insulation layer (50A) is thereby formed (refer to FIG. 9D). The process after that is identical to that of the first embodiment. In the second modified example of the first embodiment, stress caused by the difference in thermal expansion coefficients between the semiconductor element 110 and the insulative base material (30z) is effectively relieved.

### Second Embodiment

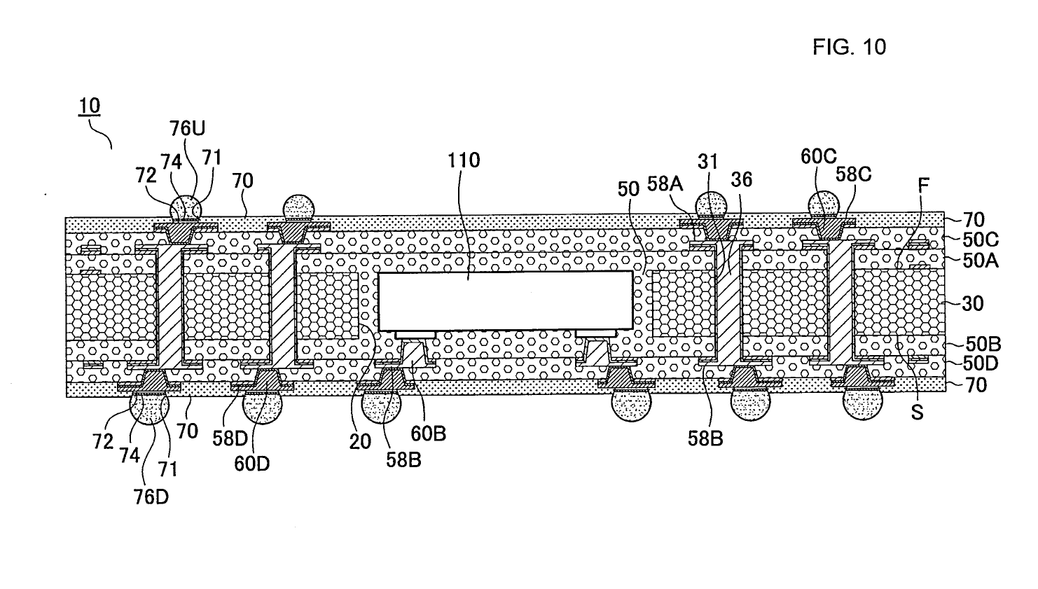

FIG. 10 illustrates a cross section of a wiring board 10 with a built-in electronic component according to a second embodiment of the present invention.

The wiring board 10 with a built-in electronic component is provided with an insulative base material 30, and a semiconductor element 110 is accommodated in a through hole 20 provided in the insulative base material 30.

A first buildup layer is formed on the semiconductor element 110 and a first surface (F) of the insulative base material 30. The first buildup layer includes an insulation layer (50A) formed so as to cover the semiconductor element 110 and the first surface (F) of the insulative base material 30, and a conductive layer (58A) on the insulation layer (50A). An insulation layer (50C) is further formed on the insulation layer (50A) and conductive layer (58A), and a conductive layer (58C) is formed on the insulation layer (50C). The conductive layers (58A, 58C) are connected to each other through a via conductor (60C) formed in the insulation layer (50C).

A second buildup layer is formed on the semiconductor element 110 and on a second surface (S) of the insulative base material 30. The second buildup layer includes an insulation layer (50B) formed on the semiconductor element 110 and the second surface (S) of the insulative base material 30, and a conductive layer (58B) on the insulation layer (50B). An insulation layer (50D) is further formed on the insulation layer (50B) and conductive layer (58B), and a conductive layer (58D) is formed on the insulation layer (50D). The conductive layers (58B, 58D) are connected to each other through a via conductor (60D) formed in the insulation layer (50D).

A through hole 31 is formed which penetrates through the insulative base material 30, insulation layer (50A) and insulation layer (50B); in the through hole 31, a through-hole conductor 36 is formed by filling a plating film. The end portion of the through-hole conductor 36 on its first-surface side is connected to the conductive layer (58A) on the insulation layer (50A), and the end portion of the through-hole conductor 36 on its second-surface side is connected to the conductive layer (58B) on the insulation layer (50B). In the insulation layer (50B), a via conductor (60B) is formed for connection to a connection terminal 112 of the semiconductor element 110, and the end portion of the via conductor (60B) on its second-surface side is connected to the conductive layer (58B) on the insulation layer (50B).

As with the first embodiment described above with reference to FIGS. 2A, 2B, 2C, also in the wiring board 10 with a built-in electronic component, projections 22 are provided in the through hole 20, and the wiring board 10 with a built-in electronic component with hardly any warping is obtained, while the amount of positional shift of the semiconductor element 110 in the through hole 20 is reduced.

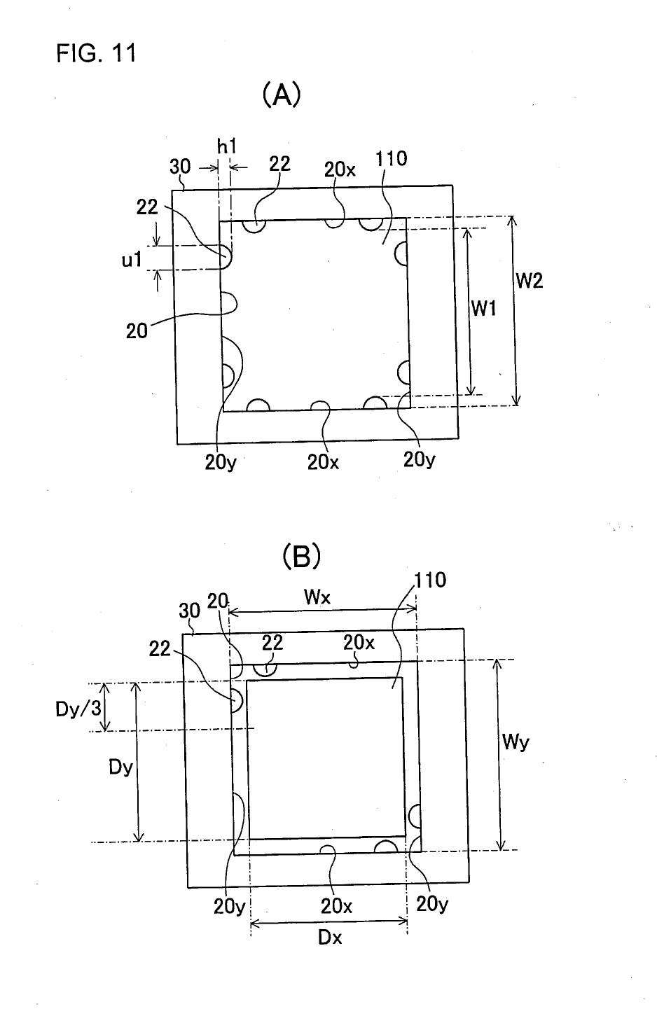

In FIG. 11A, the size of the projections 22 formed in the through hole 20 is indicated.

The height h1 (distance from a side wall to the semiconductor element) of the projections 22 is preferred to be 5 μm to 40 μm.

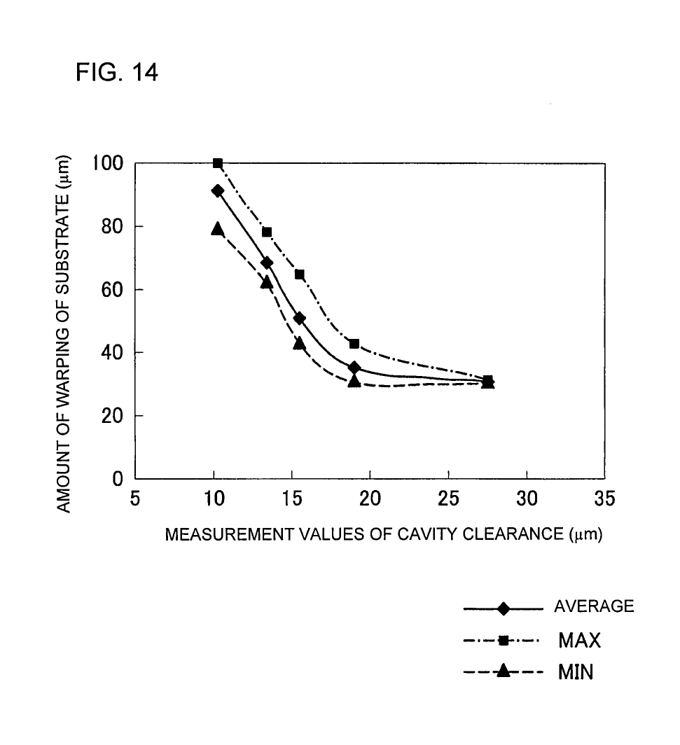

FIG. 14 presents the results of measuring the amount of warping of a substrate by use of an 8-mm-square semiconductor element. In the graph, the amount of warping (in units of μm) of the substrate is plotted on the vertical axis, and measurement values of cavity clearance (in units of μm), i.e., the clearance between an electronic component and a side wall of a cavity, are plotted on the lateral axis. Average values for predetermined number of substrates (10 substrates), maximum values and minimum values are indicated by rhombus marks, square marks and triangle marks in the graph, respectively. Since the maximum allowable value of the amount of warping is 80 μm, the clearance between the electronic component and a side wall of the cavity is preferred to be equal to or more than 12 μm.

When a clearance equal to or more than 20 μm is ensured between the electronic component and a side wall of the cavity, warping problems do not arise. In a case in which a clearance of only 15 μm is ensured between the electronic component and a side wall of the cavity for the sake of positioning accuracy, by rendering the clearance between the electronic component and a side wall of the cavity to be 20 μm and forming projections each having a height of 5 μm, the clearance between the electronic component and the tip end of the projection is rendered to be 15 μm and warping is suppressed without losing positioning accuracy. It is noted that, if the clearance between the electronic component and a side wall of the cavity exceeds 40 μm, positioning accuracy with respect to the cavity decreases even though the projections are provided, so the clearance is preferred to be equal to or less than 40 μm. The width (u1) of the projection 22 is preferred to be approximately the same as or twice as great as the height (h1) in order to ensure the strength.

In FIG. 11B, the size of the through hole 20 with respect to the external shape of the semiconductor element 110 is indicated. It is preferred that the through hole 20 be larger by the order of 80 μm with respect to the external dimensions (Dy)×(Dx) of the semiconductor element 110. That is, it is preferred that the external dimensions of the through hole 20 be (Dx) (=Wx+80 μm)×(Dy) (=Wy+80 μm). The projections 22 are each preferred to be formed in the vicinity of a corner of the semiconductor element 110 in order to enhance positioning accuracy. The tip end of the projection 22 in the y-axis direction is preferred to be in the range from the corner of the semiconductor element 110 to one third of the width (Dy) thereof.

Moreover, when the widths of the cavity 20 facing each other are (Wx, Wy), the widths of the semiconductor element 110 are (Dx, Dv), and the protruding amount of each of the projections 22 is (h1) in FIG. 11A, the following is preferred:

(Wx−Dx)/2≦5 h1

(Wy−Dy)/2≦5 h1

Both positioning accuracy and the prevention of warping become mutually compatible.

Regarding the number of the projections 22, two projections 22 may be positioned on each of the side walls (20x, 20x) facing each other and also on each of the side walls (20y, 20y) facing each other as illustrated in FIG. 11A. In this case, the respective projections 22 are formed to face each other across the semiconductor element 110.

Alternatively, one projection 22 may be positioned on each of the side walls (20x, 20x) and also each of the side walls (20y, 20y) as illustrated in FIG. 11B. In this case, the projections 22 are formed at positions interposing each of the corners of the semiconductor element 110 facing each other.

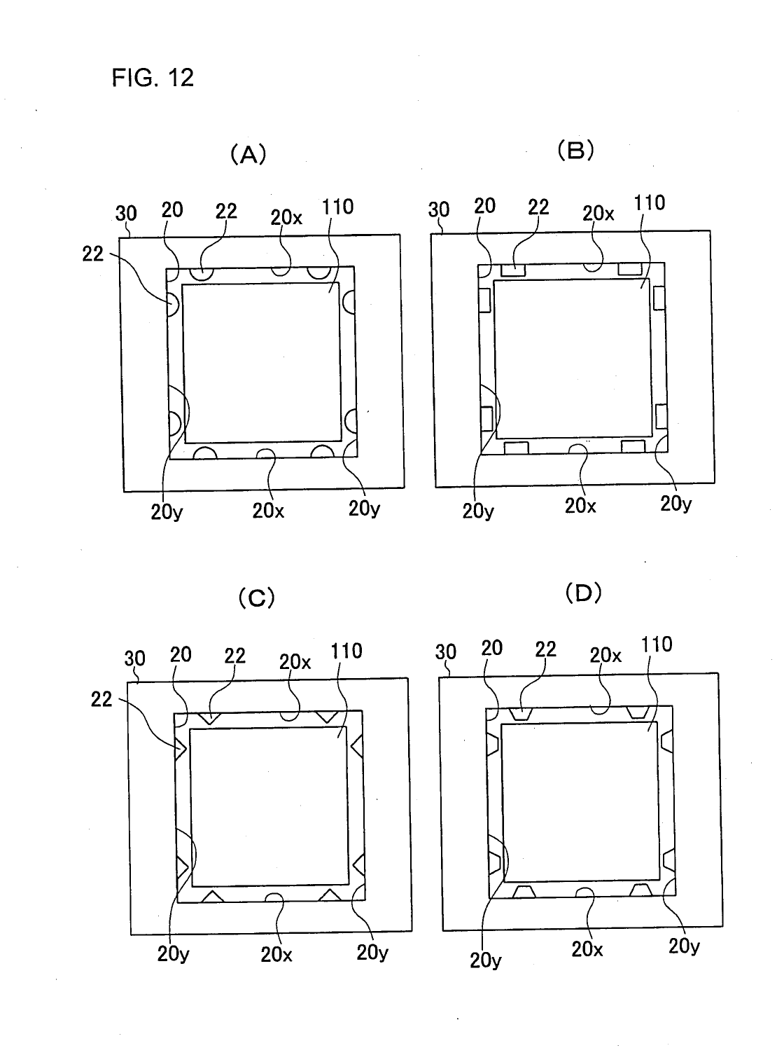

As the shape of the projection 22, a rectangle as illustrated in FIG. 12B, a triangle as illustrated in FIG. 12C, or a trapezoid as illustrated in FIG. 12D can be employed besides the semicircle illustrated in FIG. 12A.

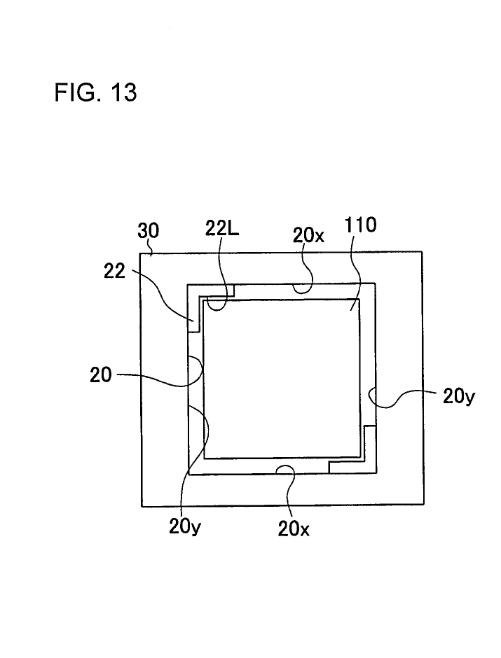

It is also an option to use a pair of L-shaped portions (22L) as the projections 22 to hold the corners of the semiconductor element 110 at the corners of the through holes 20, as illustrated in FIG. 13.

Although a semiconductor element is exemplified as an active electronic component to be built in a wiring board with a built-in electronic component in the above embodiments, a structure according to an embodiment of the present invention is suitable for use in the cases in which a passive electronic component such as a chip condenser, inductor, resistor or the like is built in.

When a cavity size is made large with respect to the size of the built-in semiconductor element, the accuracy of connecting a via to the semiconductor element may drop and connection reliability may decrease. On the other hand, when a cavity size is made small with respect to the size of the built-in semiconductor element, a printed wiring board may be apt to warp because of a reduction in the amount of filling resin in the cavity; the filling resin relieves stress caused by the difference in thermal expansion coefficients of the semiconductor element and resin substrate.

A wiring board with a built-in electronic component according to an embodiment of the present invention reduces the amount of positional shift of the electronic component in a cavity and still resists warping, and another embodiment of the present invention is a method for manufacturing such a wiring board with a built-in electronic component.

A wiring board with a built-in electronic component according to an embodiment of the present invention includes a substrate having a cavity, an electronic component accommodated in the cavity, a filling resin filled between an inner wall of the cavity and the electronic component, an insulation layer formed on the substrate and the electronic component, and a via conductor, which is formed in the insulation layer and is connected to a connection terminal of the electronic component. Two or more projections protruding toward the electronic component are provided on an inner wall of the cavity.

In a wiring board with a built-in electronic component according to an embodiment of the invention, since the two or more projections, which protrude toward the electronic component and restrain the position of the electronic component, are provided on the inner wall of the cavity for accommodating the electronic component, the accuracy of positioning the electronic component with respect to the cavity is enhanced and the amount of the positional shift of the electronic component in the cavity decreases. In addition, since the projections are provided for positioning and the size of the cavity is not required to be reduced in response to the size of the electronic component, the cavity can be filled with the filling resin of the amount sufficient to relieve the stress caused by the difference in thermal expansion coefficients of the electronic component and resin substrate, and warping of the wiring board with the built-in electronic component due to stress caused by the difference in thermal expansion coefficients occurs hardly at all.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board for a built-in electronic component, comprising:
a substrate having a cavity portion;
an electronic component accommodated in the cavity portion of the substrate;
a filling resin material filling a space formed between the electronic component and an inner wall of the substrate forming the cavity portion;
an insulation layer formed on the substrate and the electronic component accommodated in the cavity portion of the substrate; and
a via conductor formed in the insulation layer such that the via conductor is connected to a connection terminal of the electronic component,
wherein the substrate has a plurality of projection portions formed on the inner wall of the substrate such that the projection portions project toward the electronic component accommodated in the cavity portion of the substrate.

2. The wiring board according to claim 1, wherein the cavity portion of the substrate has a rectangular shape, and the plurality of projection portions is formed such that the projection portions are positioned on opposite sides of the inner wall across the electronic component.

3. The wiring board according to claim 1, wherein the cavity portion of the substrate has a rectangular shape, and the plurality of projection portions is formed such that the projection portions are positioned on opposite sides of the inner wall and facing directly across the electronic component.

4. The wiring board according to claim 1, wherein the cavity portion of the substrate has a rectangular shape, and the plurality of projection portions is formed such that the projection portions are positioned on opposite corners of the inner wall diagonally across the electronic component.

5. The wiring board according to claim 3, wherein the electronic component and the substrate satisfy (W−D)/2≦5 h, where W represents a width of the cavity portion, D represents a width of the electronic component, and h represents a length of each of the projection portions projecting from the inner wall of the substrate.

6. The wiring board according to claim 1, wherein the filling resin material has an elastic modulus which is smaller than an elastic modulus of the substrate and an elastic modulus of the electronic component.

7. The wiring board according to claim 1, wherein the electronic component is positioned in the cavity portion of the substrate such that the filling resin material is filling clearances formed between the electronic component and tip ends of the projection portions of the substrate.

8. The wiring board according to claim 1, wherein the plurality of projection portions is formed such that the projection portions are positioned on opposite sides of the inner wall across the electronic component, and the electronic component is positioned in the cavity portion of the substrate such that clearances formed between the electronic component and tip ends of the projection portions of the substrate have different distances.

9. The wiring board according to claim 1, wherein each of the projection portions has one of a semicircle shape, a rectangle shape, a triangle shape and a trapezoid shape.

10. The wiring board according to claim 1, wherein each of the projection portions has a semicircle shape.

11. The wiring board according to claim 1, wherein the plurality of projection portions is formed such that the projection portions are positioned on opposite sides of the inner wall across the electronic component.

12. The wiring board according to claim 1, wherein the cavity portion of the substrate has a rectangular shape, and the plurality of projection portions is formed such that each side of the inner wall has at least one of the projection portions.

13. The wiring board according to claim 1, wherein the plurality of projection portions is positioned such that the electronic component is restrained in a position in the cavity portion of the substrate.

14. The wiring board according to claim 1, wherein the plurality of projection portions is configured to restrain the electronic component in the cavity portion of the substrate.

15. The wiring board according to claim 1, wherein at least one of the filling resin material and the insulation layer includes inorganic particles in an amount such that the filling resin material has a thermal expansion coefficient between a thermal expansion coefficient of the electronic component and a thermal expansion coefficient of the insulation layer.

16. A method for manufacturing a wiring board having a built-in electronic component, comprising:
preparing a substrate having a cavity portion and a plurality of projection portions on an inner wall of the substrate forming the cavity portion;
placing an electronic component in the cavity portion of the substrate such that the electronic component is accommodated in the cavity portion of the substrate;
filling a filling resin material into a space formed between the electronic component and the inner wall of the substrate forming the cavity portion;
forming an insulation layer on the substrate and the electronic component accommodated in the cavity portion of the substrate; and
forming a via conductor in the insulation layer such that the via conductor is connected to a connection terminal of the electronic component,
wherein the plurality of projection portions is formed on the inner wall of the substrate such that the projection portions project toward the electronic component accommodated in the cavity portion of the substrate.

17. The method for manufacturing a wiring board having a built-in electronic component according to claim 16, wherein the filling of the filling resin material and the forming of the insulation layer are carried out in a same process.

18. The method for manufacturing a wiring board having a built-in electronic component according to claim 16, wherein the electronic component is positioned in the cavity portion of the substrate such that the filling of the filling resin material includes filling the filling resin material in clearances formed between the electronic component and tip ends of the projection portions of the substrate.

19. The method for manufacturing a wiring board having a built-in electronic component according to claim 16, further comprising:
semi-curing the filling resin material filled in the space formed between the electronic component and the inner wall of the substrate,
wherein the forming of the insulation layer includes thermo-pressing the insulation layer onto the substrate and the electronic component accommodated in the cavity portion of the substrate after the semi-curing of the filling resin material.

20. The method for manufacturing a wiring board having a built-in electronic component according to claim 16, wherein the preparing of the substrate includes forming the cavity portion and forming the projection portions in a same process.
